(19) United States
(12) Patent Application Publication
(10) Pub. No.: US 2017/0278992 A1
(43) Pub. Date: Sep. 28, 2017

(54) SOLAR CELL MODULE AND METHOD FOR MANUFACTURING SOLAR CELL MODULE

(71) Applicant: Panasonic Intellectual Property Management Co., Ltd., Osaka (JP)

(72) Inventors: Masao KOUYANAGI, Osaka (JP); Mamoru YAMASHITA, Osaka (JP); Hitomi ICHINOSE, Osaka (JP); Takahiro NAKAMURA, Osaka (JP)

(73) Assignee: Panasonic Intellectual Property Management Co., Ltd., Osaka (JP)

(21) Appl. No.: 15/512,066

(22) PCT Filed: Aug. 20, 2015
(86) PCT No.: PCT/JP2015/004167

§ 371 Date: Mar. 17, 2017

(30) Foreign Application Priority Data
Sep. 22, 2014 (JP) 2014-192732

(51) Int. Cl. H01L 31/049; H01L 31/02; H01L 31/0475

(52) U.S. Cl. CPC H01L 31/049; H01L 31/0475; H01L 31/02013

(57) ABSTRACT

A solar cell module includes: a substrate; a back sheet; a plurality of solar cells arranged between the substrate and the back sheet; a transition wire common-connecting tab wires connected to the plurality of solar cells; a concealment sheet covering the transition wire from a substrate side; and a filling member filling at least a space between the transition wire and the concealment sheet, wherein the concealment sheet includes: a first sheet layer in contact with the filling member; and a second sheet layer placed over the first sheet layer, the first sheet layer and the second sheet layer are each made of any of: a material of a same type of color as a material of the back sheet or the filling member; a transparent material; and a semitransparent material, and the first sheet layer has adhesiveness to the filling member.

### TECHNICAL FIELD

The present invention relates to a solar cell module and a method for manufacturing a solar cell module.

### BACKGROUND ART

Solar cell modules have been conventionally developed as photoelectric conversion devices for converting light energy into electric energy. Solar cell modules are expected to serve as a new energy source, as they can convert inexhaustible sunlight directly into electricity and also are environmentally friendly and clean as compared with fossil fuel power generation.

This type of solar cell module has, for example, a structure in which a plurality of solar cells are sealed with a filler between a light-transmitting substrate and a back sheet. For example, the solar cell module includes: a glass substrate located on the light receiving surface side; a back sheet; a plurality of solar cells arranged in a matrix between the glass substrate and the back sheet; and a filling member filling the space between the back sheet and the glass substrate (for example, Patent Literature (PTL) 1).

A plurality of solar cells arranged in one of the row direction and column direction are made into a cell string by connecting adjacent solar cells by tab wires. Transition wires are provided at both ends of the solar cell module, and the first and last solar cells in each of a plurality of cell strings are connected to the transition wires via the tab wires.

### CITATION LIST

### Patent Literature

PTL 1: Japanese Unexamined Patent Application Publication No. 2007-150069

### SUMMARY OF THE INVENTION

### Technical Problem

The transition wires, however, have metallic luster in appearance, and so are noticeable in the case where the solar cell module is seen from the light receiving surface side. This causes a problem of poor design of the whole appearance of the solar cell module.

To conceal the transition wires, the transition wires may be covered with a concealment sheet from the light receiving surface side. The placement of the concealment sheet can, however, degrade design, and also degrade workability.

The present invention has been made to solve the problem stated above, and has an object of providing a solar cell module that can conceal transition wires without degrading design and workability.

### Solution to Problem

To solve the problem stated above, one aspect of a solar cell module according to the present invention is a solar cell module including: a light-transmitting substrate; a back sheet; a plurality of solar cells arranged between the substrate and the back sheet; a transition wire common-connecting tab wires connected to the plurality of solar cells; a concealment sheet covering the transition wire from a substrate side; and a filling member filling a space between the substrate and the back sheet, wherein the concealment sheet includes: a first sheet layer in contact with the filling member; and a second sheet layer placed over the first sheet layer, the first sheet layer and the second sheet layer are each made of any of: a material of a same type of color as a material of the back sheet or the filling member; a transparent material; and a semitransparent material, and the first sheet layer has adhesiveness to the filling member.

One aspect of a method for manufacturing a solar cell module according to the present invention is a method for manufacturing a solar cell module including a light-transmitting substrate and a back sheet, the method including arranging, between the substrate and the back sheet, a plurality of solar cells, a transition wire common-connecting tab wires connected to the plurality of solar cells, a concealment sheet covering the transition wire from a substrate side, and a filling member, wherein the concealment sheet includes: a first sheet layer in contact with the filling member; and a second sheet layer placed over the first sheet layer, the first sheet layer and the second sheet layer are each made of any of: a material of a same type of color as a material of the back sheet or the filling member; a transparent material; and a semitransparent material, and the first sheet layer has adhesiveness to the filling member.

### Advantageous Effect of Invention

It is thus possible to conceal transition wires without degrading design and workability.

### BRIEF DESCRIPTION OF DRAWINGS

FIG. 1 is a plan view of a solar cell module according to an embodiment.

FIG. 2 is a partially enlarged sectional view (sectional view along line A-A in FIG. 1) of the solar cell module according to the embodiment.

FIG. 3 is a view for describing a lamination process in the solar cell module according to the embodiment.

FIG. 4A is a sectional view (sectional view before lamination) illustrating the structure of a solar cell module according to a comparative example.

FIG. 4B is a sectional view (sectional view after lamination) illustrating the structure of the solar cell module according to the comparative example.

### DESCRIPTION OF EXEMPLARY EMBODIMENT

The following describes an embodiment of the present invention with reference to drawings. The embodiment described below shows a specific example of the present invention. The numerical values, shapes, materials, structural elements, the arrangement and connection of the structural elements, etc. shown in the following embodiment are mere examples, and do not limit the scope of the present invention. Of the structural elements in the embodiment described below, the structural elements not recited in any one of the independent claims representing the broadest concepts of the present invention are described as optional structural elements.

Each drawing is a schematic and does not necessarily provide precise depiction. The substantially same structural elements are given the same reference signs throughout the drawings, and their detailed description is omitted or simplified.

### Embodiment

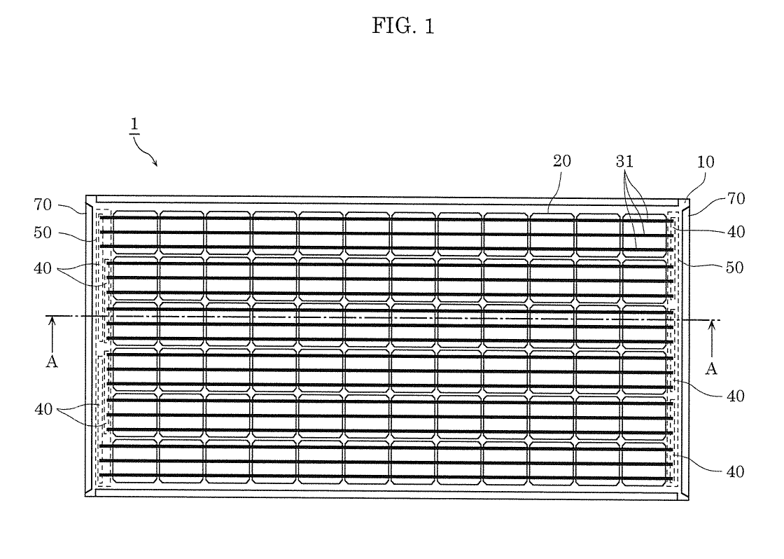

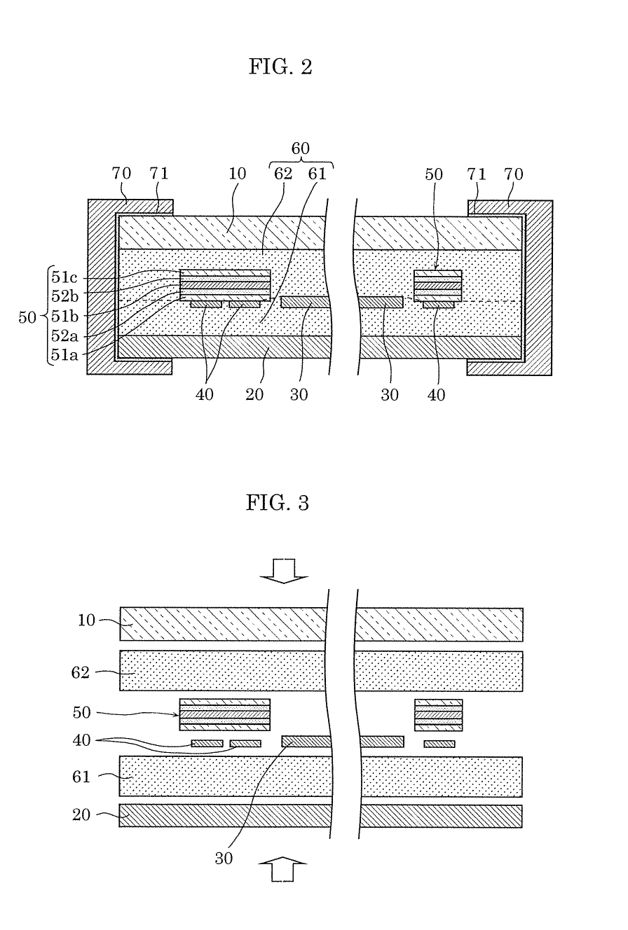

The structure of solar cell module 1 according to the embodiment is described first, with reference to FIGS. 1 and 2. FIG. 1 is a plan view of the solar cell module according to the embodiment. FIG. 2 is a partially enlarged sectional view of the solar cell module along line A-A in FIG. 1.

As illustrated in FIGS. 1 and 2, solar cell module 1 includes substrate 10, back sheet 20, plurality of solar cells 30, transition wire 40, concealment sheet 50, and filling member 60. Solar cell module 1 in this embodiment further includes frame 70. Solar cell module 1 has a structure in which solar cells 30 are sealed with filling member 60 between substrate 10 and back sheet 20 that face each other.

As illustrated in FIG. 1, solar cell module 1 is, for example, rectangular in planar view. As an example, solar cell module 1 is a rectangle of about 1600 mm in horizontal length and about 800 mm in vertical length. The shape of solar cell module 1 is not limited to a rectangle.

The following describes each structural member of solar cell module 1 in detail.

[Substrate]

Substrate 10 is a light-transmitting substrate, and is, for example, a glass substrate (transparent glass substrate) made of a transparent glass material. Substrate 10 is not limited to a glass substrate, and may be, for example, a resin substrate made of a light-transmitting resin material such as a transparent resin material.

Substrate 10 is a front surface protection member for protecting the front surface of solar cell module 1, and protects the inside of solar cell module 1 from the external environment such as the wind and rain, external impact, and fire. In this embodiment, substrate 10 is located on the light receiving surface side of solar cells 30, and sunlight enters from the substrate 10 side. The surface (exposed surface) of substrate 10 is thus the light receiving surface. An antireflection coating may be formed on the surface of substrate 10, to make substrate 10 a low-reflection substrate.

[Back sheet]

Back sheet 20 is a back surface protection member for protecting the back surface of solar cell module 1, and protects the inside of solar cell module 1 from the external environment. Back sheet 20 is, for example, a resin sheet made of polyethylene terephthalate (PET) or polyethylene naphthalate (PEN).

In this embodiment, the color of back sheet 20 is black. The color of back sheet 20 may be, however, other than black. Back sheet 20 is not limited to be made of resin, and may be made of glass.

[Solar Cell (solar Cell Element)]

Solar cell 30 is a photoelectric conversion element (photovoltaic element) for converting light such as sunlight into electricity. As illustrated in FIG. 1, plurality of solar cells 30 are arranged in a matrix on the same plane to form a cell array. As illustrated in FIG. 2, plurality of solar cells 30 (cell array) are arranged between substrate 10 and back sheet 20.

Plurality of solar cells 30 arranged in one of the row direction and column direction are made into a cell string (solar cell group) by electrically connecting adjacent solar cells 30 by conductive tab wire (interconnector) 31. Plurality of solar cells 30 in the cell string are connected in series. Tab wire 31 may be, for example, made by cutting metal foil, such as copper foil or silver foil, the entire surface of which is coated with solder, in strip form with a predetermined length.

In this embodiment, plurality of solar cells 30 arranged in the row direction are connected by tab wire 31 to form a cell string. In this case, the respective electrodes of adjacent solar cells 30 are connected in sequence by three tab wires 31 through solder or the like, thus creating a cell string in which plurality of solar cells 30 are connected in a line.

In FIG. 1, each solar cell 30 is connected with three tab wires 31, and twelve solar cells 30 are connected along the row direction to constitute one cell string. Six cell strings are formed in FIG. 1.

[Transition Wire (Transition Tab)]

Transition wire 40 is horizontal wiring common-connecting tab wires 31 connected to plurality of solar cells 30. Transition wire 40 may be, for example, made by cutting metal foil, such as copper foil or silver foil, the entire surface of which is coated with solder, in strip form with a predetermined length.

As illustrated in FIG. 1, transition wire 40 is provided at both ends of solar cell module 1 in the longitudinal direction. In this embodiment, four transition wires 40 are provided at one end (left end in FIG. 1) of solar cell module 1 in the longitudinal direction, and two transition wires 40 are provided at the other end (right end in FIG. 1) of solar cell module 1 opposite to the one end in the longitudinal direction.

The first solar cell 30 in each cell string is electrically connected to transition wires 40 via tab wires 31, in the vicinity of the one end of solar cell module 1 in the longitudinal direction. The last solar cell 30 in each cell string is electrically connected to transition wires 40 via tab wires 31, in the vicinity of the other end of solar cell module 1 in the longitudinal direction.

Thus, the plurality of (six in FIG. 1) cell strings are connected in series or in parallel to constitute the cell array. In other words, all solar cells 30 in solar cell module 1 are connected in series or in parallel.

[Concealment Sheet]

Concealment sheet 50 covers transition wires 40 from the substrate 10 side, in order to conceal transition wires 40. Hence, concealment sheet 50 overlaps transition wires 40 and is greater in size than transition wires 40 in planar view, as illustrated in FIG. 1.

In this embodiment, transition wires 40 are provided at both ends of solar cell module 1 in the longitudinal direction, i.e. at two locations that are the one end and other end in the longitudinal direction. Concealment sheet 50 is accordingly provided at both ends of solar cell module 1 in the longitudinal direction.

In this embodiment, concealment sheet 50 provided at the one end (left end in FIG. 1) of solar cell module 1 in the longitudinal direction covers all (four in FIG. 1) transition wires 40 located at the one end together. Concealment sheet 50 provided at the other end (right end in FIG. 1) of solar cell module 1 in the longitudinal direction covers all (two in FIG. 1) transition wires 40 located at the other end together.

As illustrated in FIG. 2, concealment sheet 50 has a stack structure of a plurality of layers, and includes: first sheet layer 51a in contact with filling member 60; and second sheet layer 51b placed over first sheet layer 51a. Concealment sheet 50 in this embodiment further includes third sheet layer 51c placed over second sheet layer 51b. Concealment sheet 50 thus has a stack structure of three sheet layers. As an example, first sheet layer 51a and third sheet layer 51c each have a layer thickness of 30 μm, and second sheet layer 51b has a layer thickness of 50 μm.

First sheet layer 51a and second sheet layer 51b are made of any of: a material of the same type of color as the material of back sheet 20 or filling member 60 (back sheet side filling member 61); a transparent material; and a semitransparent material.

In this embodiment, first sheet layer 51a is made of a transparent material. Second sheet layer 51b is made of a material of the same type of color as the material of back sheet 20 or filling member 60 (back sheet side filling member 61), and is made of a black material to match the color of back sheet 20 in this embodiment. Third sheet layer 51c is made of the same material (transparent material) as first sheet layer 51.

Thus, in this embodiment, given that the color of back sheet 20 or filling member 60 which is the background color of concealment sheet 50 is black, a layer of white color which is noticeable in the case where the background color is black is not used in any of the sheet layers included in concealment sheet 50.

In this embodiment, first sheet layer 51a is a resin sheet (PE sheet) made of polyethylene (PE), and second sheet layer 51b is a resin sheet (PET sheet) made of polyethylene terephthalate (PET). Third sheet layer 51c is made of the same material as first sheet layer 51a, and is a resin sheet (PE sheet) made of polyethylene (PE) in this embodiment.

First sheet layer 51a has adhesiveness to filling member 60. This enables first sheet layer 51a and filling member 60 to adhere to each other, without interposing an additional adhesive in between.

In detail, first sheet layer 51a has adhesiveness to filling member 60 filling the space between transition wires 40 and concealment sheet 50. In this embodiment, first sheet layer 51a is in contact with back sheet side filling member 61, and has adhesiveness to back sheet side filling member 61. This enables first sheet layer 51a and back sheet side filling member 61 to adhere to each other without using an adhesive.

An experiment by the present inventors revealed that polyethylene (PE) and ethylene vinyl acetate (EVA) adhered to each other without using an additional adhesive. Accordingly, first sheet layer 51a made of PE and back sheet side filling member 61 made of EVA adhere to each other without using an adhesive.

Third sheet layer 51c also has adhesiveness to filling member 60. This enables third sheet layer 51c and filling member 60 to adhere to each other, without interposing an additional adhesive in between.

In detail, third sheet layer 51c has adhesiveness to filling member 60 filling the space between substrate 10 and concealment sheet 50. In this embodiment, third sheet layer 51c is in contact with substrate side filling member 62, and has adhesiveness to substrate side filling member 62. This enables third sheet layer 51c and substrate side filling member 62 to adhere to each other without using an adhesive.

Polyethylene (PE) and ethylene vinyl acetate (EVA) adhere to each other as mentioned above, and so third sheet layer 51c made of PE and substrate side filling member 62 made of EVA adhere to each other without using an adhesive. In this embodiment, first sheet layer 51a and third sheet layer 51c adhere to and merge with filling member 60 after a lamination process.

In this embodiment, the material of second sheet layer 51b is PET. This realizes concealment sheet 50 having favorable long-term reliability and necessary strength (stiffness) in appearance. The use of PET as the material of second sheet layer 51b also facilitates operation in the manufacturing process. In detail, in the manufacturing process, substrate 10 (glass), substrate side filling member 62, and transition wires 40 are stacked in this order, and concealment sheet 50 is inserted between substrate side filling member 62 and transition wires 40. For example, transition wires 40 are lifted with tweezers, and concealment sheet 50 is inserted into the gap between transition wires 40 and substrate side filling member 62. Here, the use of PET with relatively high strength as the material of second sheet layer 51b facilitates the operation of inserting concealment sheet 50.

Concealment sheet 50 further includes: first adhesion layer 52a for causing first sheet layer 51a and second sheet layer 51b to adhere to each other; and second adhesion layer 52b for causing second sheet layer 51b and third sheet layer 51c to adhere to each other.

Inserting first adhesion layer 52a between first sheet layer 51a and second sheet layer 51b eases the adhesion between first sheet layer 51a and second sheet layer 51b. Inserting second adhesion layer 52b between second sheet layer 51b and third sheet layer 51c eases the adhesion between second sheet layer 51b and third sheet layer 51c.

In this embodiment, the color of first adhesion layer 52a and second adhesion layer 52b is black to match the color of back sheet 20.

Thus, in this embodiment, given that the color of back sheet 20 or filling member 60 which is the background color of concealment sheet 50 is black, a layer of white color which is noticeable in the case where the background color is black is not used in any of the resin layers included in concealment sheet 50, either.

Concealment sheet 50 having the aforementioned structure can be produced in the following manner. For example, a structure obtained by bonding three plate-like sheet layers of plate-like first sheet layer 51a, plate-like second sheet layer 51b, and plate-like third sheet layer 51c by adhesion with two adhesion layers of first adhesion layer 52a and second adhesion layer 52b is cut in strip form with a predetermined length. Since concealment sheet 50 in this embodiment covers plurality of transition wires 40 located at each of both ends of solar cell module 1 in the longitudinal direction together, the length of concealment sheet 50 is approximately the length of the short side of solar cell module 1.

[Filling Member]

Filling member (filler) 60 is located between substrate 10 and back sheet 20. In this embodiment, filling member 60 fills the space between substrate 10 and back sheet 20. Solar cells 30 are thus sealed with filling member 60.

Filling member 60 is formed by performing a lamination process (lamination) on the two filling members sandwiching solar cells 30. The lamination process is described below, with reference to FIG. 3. FIG. 3 is a view for describing the lamination process in the solar cell module according to the embodiment.

As illustrated in FIG. 3, the plurality of cell strings composed of plurality of solar cells 30 are sandwiched between back sheet side filling member 61 and substrate side filling member 62, and back sheet 20 and substrate 10 are placed below and above the sandwich structure, to prepare a predetermined stack body.

The stack body is then subjected to thermocompression bonding (heating and pressing) in a vacuum at a temperature of 100° C. or higher as an example. As a result, back sheet side filling member 61 and substrate side filling member 62 are heated to melt, and form filling member 60.

By performing such a lamination process, the space between substrate 10 and back sheet 20 is filled with filling member 60, and solar cells 30, transition wires 40, and concealment sheet 50 are sealed with filling member 60.

Back sheet side filling member (first filling member) 61 is a sheet located between back sheet 20 and each of; plurality of solar cells 30; and transition wires 40, and mainly fills the space between back sheet 20 and transition wires 40 and solar cells 30 as a result of the lamination process.

Substrate side filling member (second filling member) 62 is a sheet located between substrate 10 and each of; plurality of solar cells 30; and concealment sheet 50, and mainly fills the space between substrate 10 and solar cells 30 and concealment sheet 50 as a result of the lamination process.

Each of back sheet side filling member 61 and substrate side filling member 62 is, for example, a resin sheet made of a resin material, and is an EVA sheet made of ethylene vinyl acetate (EVA) in this embodiment. The color of back sheet side filling member 61 and substrate side filling member 62 is, for example, black. The color of filling member 60 is therefore black.

[Frame]

Frame 70 is an outer frame covering the peripheral edges of solar cell module 1. Frame 70 in this embodiment is an aluminum frame made of aluminum. As illustrated in FIG. 1, four frames 70 are attached to the respective edges of the four sides of solar cell module 1.

As illustrated in FIG. 2, for example, frame 70 is bonded to the edge of each side of solar cell module 1 by adhesive 71 made of silicone resin.

The solar cell module is provided with a terminal box for extracting power generated in solar cells 30, although not illustrated. For example, the terminal box is fixed to back sheet 20, and contains a plurality of circuit components mounted on a circuit substrate.

[Advantageous Effects, etc.]

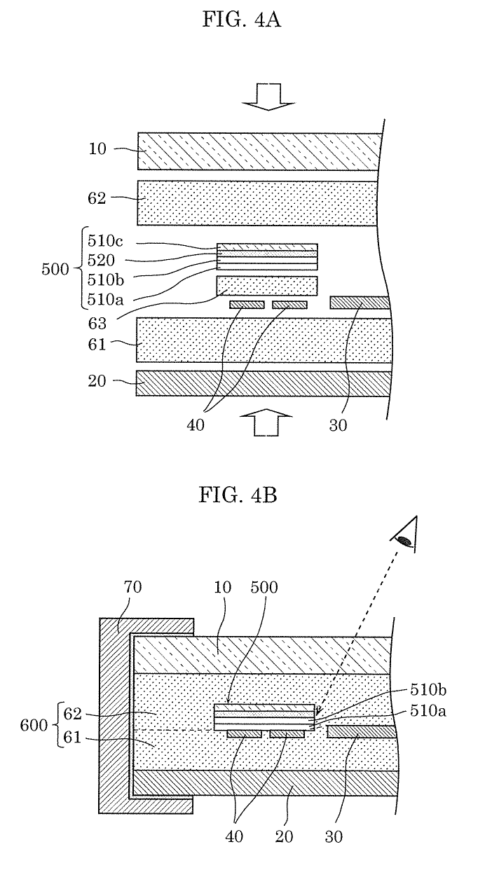

The following describes the advantageous effects of solar cell module 1 according to this embodiment together with the circumstances leading to the present invention, with reference to FIGS. 4A and 4B illustrating a comparative example. FIGS. 4A and 4B are sectional views illustrating the structure of a solar cell module according to the comparative example. FIG. 4A illustrates the structure before the lamination process, and FIG. 4B illustrates the structure after the lamination process.

In the solar cell module, the first and last solar cells in each cell string are connected to the transition wires via the tab wires. Here, the transition wires have metallic luster, and so are noticeable in the case where the solar cell module is seen from the glass substrate side. This causes poor design of the solar cell module as a whole.

In view of this, the present inventors studied covering transition wires 40 with concealment sheet 500 from the substrate 10 side (light receiving surface side) to conceal transition wires 40, as illustrated in FIGS. 4A and 4B.

Concealment sheet 500 studied here had a structure in which stack PET composed of first sheet layer 510a (38 μm) made of PET and second sheet layer 510b (50 μm) made of PET was caused to adhere to third sheet layer 510c made of PE by adhesion layer 520. First sheet layer 510a and second sheet layer 510b were white, third sheet layer 510c was transparent, and adhesion layer 520 was black.

The introduction of concealment sheet 500 was thus studied in order to improve design. However, providing concealment sheet 500 ended up rather degrading design. This is described in detail below.

The materials and colors of first sheet layer 510a, second sheet layer 510b, adhesion layer 520, and third sheet layer 510c in concealment sheet 500 were selected as mentioned above, for color matching with back sheet 20 and the like.

However, due to the presence of black color of back sheet 20 or filling member 600 as the background color of concealment sheet 500, the edges of white first sheet layer 510a and white second sheet layer 510b were visible from the light receiving surface depending on the angle from which the solar cell module was seen, as illustrated in FIG. 4B. In other words, white lines (streaky white lines) could be visible along the longitudinal direction of concealment sheet 500, causing poor design.

In particular, while concealment sheet 500 was formed by cutting the stacked sheet layers to a predetermined length, in the case where the cutting state was poor, the edges of first sheet layer 510a and white second sheet layer 510b protruded (were exposed), making white lines very visible.

Thus, the present inventors found out as a result of the study that placing concealment sheet 500 having the aforementioned structure rather degraded design.

The present inventors also found out that the use of concealment sheet 500 having the aforementioned structure caused lower workability and higher cost. This is described in detail below.

As illustrated in FIG. 4A, in the case of using concealment sheet 500 having the aforementioned structure, concealment filling member 63 needed to be placed between concealment sheet 500 and transition wires 40. In other words, concealment sheet 500 needed to adhere to transition wires 40 through concealment filling member 63.

This increased the number of parts, and led to lower workability and higher cost. Concealment filling member 63 was, for example, made of the same material (EVA sheet) as back sheet side filling member 61 and substrate side filling member 62.

The present invention was made based on such findings. As a result of keen examination, the present inventors discovered that the use of concealment sheet 50 having the structure illustrated in FIG. 2 can conceal transition wires 40 without degrading design and workability.

In detail, concealment sheet 50 used in solar cell module 1 in this embodiment includes: first sheet layer 51a in contact with at least filling member 60; and second sheet layer 51b placed over first sheet layer 51a.

First sheet layer 51a and second sheet layer 51b are made of any of: a material of the same type of color as the material of back sheet 20 or filling member 60; a transparent material; and a semitransparent material.

This makes the color of back sheet 20 or filling member 60, which is the background color of concealment sheet 50, the same type of color as concealment sheet 50 or unnoticeable, so that the edges of concealment sheet 50 are not visible.

In particular, concealment sheet 50 is not noticeable even in the case where the edges of first sheet layer 51a and second sheet layer 51b protrude from concealment sheet 50 due to a poor cutting state of concealment sheet 50.

Therefore, not only transition wires 40 can be concealed by concealment sheet 50, but also concealment sheet 50 can be made unnoticeable regardless of the cutting state of concealment sheet 50. This improves the design of the whole appearance of solar cell module 1.

Moreover, in this embodiment, first sheet layer 51a has adhesiveness to filling member 60, and so concealment filling member 63 in the comparative example in FIG. 4A can be substituted by first sheet layer 51a.

In particular, since first sheet layer 51a in this embodiment is made of polyethylene (PE), concealment filling member 63 made of EVA can be easily substituted by first sheet layer 51a made of PE.

Concealment sheet 50 can thus adhere to filling member 60 without using concealment filling member 63. This prevents an increase in the number of parts, and therefore prevents lower workability and higher cost.

As described above, solar cell module 1 according to this embodiment can conceal transition wires 40 without degrading design and workability.

Moreover, in this embodiment, first sheet layer 51a is made of the transparent material or the semitransparent material, and second sheet layer 51b has the same type of color as back sheet 20 or filling member 60. In detail, back sheet 20 or filling member 60 is black, and second sheet layer 51b is black, too.

Thus, in this embodiment, concealment sheet 50 has no white layer. This avoids such a situation where, due to the black background color of back sheet 20 or filling member 60, white lines of the concealment sheet are visible in the case where the concealment sheet has a white layer.

Moreover, in this embodiment, concealment sheet 50 further includes third sheet layer 51c placed over second sheet layer 51b, and third sheet layer 51c is made of the same material as first sheet layer 51a.

In this way, transition wires 40 can be concealed without degrading design and workability, even in the case where concealment sheet 50 further includes third sheet layer 51c.

Moreover, in this embodiment, substrate side filling member 62 fills the space between concealment sheet 50 and substrate 10, and third sheet layer 51c is in contact with substrate side filling member 62 and has adhesiveness to substrate side filling member 62.

This eases the adhesion of concealment sheet 50 to substrate side filling member 62, too. Workability in the case of using concealment sheet 50 is further improved as a result.

(Variations, etc.)

While the solar cell module according to the present invention has been described above by way of the embodiment, the present invention is not limited to the foregoing embodiment.

For example, although the foregoing embodiment describes the case where concealment sheet 50 has no white layer because back sheet 20 and filling member 60 are black, concealment sheet 50 may have no black layer in the case where back sheet 20 and filling member 60 are white.

Other modifications obtained by applying various changes conceivable by a person skilled in the art to each of the embodiments and any combinations of the structural elements and functions in the embodiments without departing from the scope of the present invention are also included in the present invention.

### REFERENCE MARKS IN THE DRAWINGS

1 solar cell module

10 substrate

20 back sheet

30 solar cell

31 tab wire

40 transition wire

50, 500 concealment sheet

51a, 510a first sheet layer

51b, 510b second sheet layer

51c, 510c third sheet layer

52a first adhesion layer

52b second adhesion layer

60, 600 filling member

61 back sheet side filling member

62 substrate side filling member

63 concealment filling member

70 frame

520 adhesion layer

1. A solar cell module comprising:
a light-transmitting substrate;
a back sheet;
a plurality of solar cells arranged between the substrate and the back sheet;
a transition wire common-connecting tab wires connected to the plurality of solar cells;
a concealment sheet covering the transition wire from a substrate side; and
a filling member filling a space between the substrate and the back sheet,
wherein the concealment sheet includes: a first sheet layer in contact with the filling member; and a second sheet layer placed over the first sheet layer,
the first sheet layer and the second sheet layer are each made of any of: a material of a same type of color as a material of the back sheet or the filling member; a transparent material; and a semitransparent material, and
the first sheet layer has adhesiveness to the filling member.

2. The solar cell module according to claim 1,
wherein the first sheet layer is made of the transparent material or the semitransparent material, and
the second sheet layer has the same type of color as the back sheet or the filling member.

3. The solar cell module according to claim 2,
wherein the back sheet or the filling member is black, and
the second sheet layer is black.

4. The solar cell module according to claim 3,
wherein the concealment sheet further includes a first adhesion layer that causes the first sheet layer and the second sheet layer to adhere to each other, and
the first adhesion layer is black.

5. The solar cell module according to claim 4,
wherein the concealment sheet further includes: a third sheet layer placed over the second sheet layer; and a second adhesion layer that causes the second sheet layer and the third sheet layer to adhere to each other.

6. The solar cell module according to claim 5,
wherein the third sheet layer is made of the same material as the first sheet layer.

7. The solar cell module according to claim 5, further comprising
a substrate side filling member filling a space between the concealment sheet and the substrate,
wherein the third sheet layer is in contact with the substrate side filling member, and has adhesiveness to the substrate side filling member.

8. The solar cell module according to claim 1,
wherein the first sheet layer is made of polyethylene,
the second sheet layer is made of polyethylene terephthalate, and
the filling member is made of ethylene vinyl acetate.

9. A method for manufacturing a solar cell module including a light-transmitting substrate and a back sheet, the method comprising
arranging, between the substrate and the back sheet, a plurality of solar cells, a transition wire common-connecting tab wires connected to the plurality of solar cells, a concealment sheet covering the transition wire from a substrate side, and a filling member,
wherein the concealment sheet includes: a first sheet layer in contact with the filling member; and a second sheet layer placed over the first sheet layer,
the first sheet layer and the second sheet layer are each made of any of: a material of a same type of color as a material of the back sheet or the filling member; a transparent material; and a semitransparent material, and
the first sheet layer has adhesiveness to the filling member.
